(19) United States
(12) Patent Application Publication
(10) Pub. No.: US 2025/0355340 A1
(43) Pub. Date: Nov. 20, 2025

(54) REFLECTIVE MASK BLANK, METHOD FOR PRODUCING REFLECTIVE MASK BLANK, REFLECTIVE MASK, AND METHOD FOR PRODUCING REFLECTIVE MASK

(71) Applicant: AGC Inc., Tokyo (JP)

(72) Inventors: Hiroshi HANEKAWA, Tokyo (JP); Yukihiro IWATA, Tokyo (JP); Yuya NAGATA, Tokyo (JP); Daijiro AKAGI, Tokyo (JP); Shunya TAKI, Koriyama-shi (JP)

(73) Assignee: AGC Inc., Tokyo (JP)

(21) Appl. No.: 19/288,412

(22) Filed: Aug. 1, 2025

Related U.S. Application Data
(63) Continuation of application No. PCT/JP2024/011707, filed on Mar. 25, 2024.

(30) Foreign Application Priority Data
Mar. 31, 2023 (JP) 2023-057859

(51) Int. Cl. G03F 1/24; G03F 7/00

(52) U.S. Cl. CPC G03F 1/24; G03F 7/0005

(57) ABSTRACT

Provided is a reflective mask blank capable of easily forming a fine mask pattern and less likely to cause reflective property deterioration of a multilayer reflective film during the production of a reflective mask. The reflective mask blank includes a substrate, a multilayer reflective film to reflect EUV light, a protective film, an absorber film and a hard mask film stacked in this order, wherein the protective film contains more than 50 at % of at least one element selected from the group consisting of rhodium, palladium, iridium and platinum, and wherein the hard mask film contains ruthenium.

### TECHNICAL FIELD

The present invention relates to a reflective mask used for EUV (Extreme Ultra Violet) exposure during an exposure process in the manufacturing of semiconductors, a method for producing a reflective mask, a reflective mask blank as an original plate of a reflective mask, and a method for producing a reflective mask blank.

### BACKGROUND ART

Recent years have seen studies of EUV lithography, which uses EUV light with a center wavelength of about 13.5 nm as a light source, for further miniaturization of semiconductor devices.

In EUV exposure, a reflective optical system and a reflective mask are used in view of the characteristics of EUV light. The reflective mask has a multilayer reflective film provided on a substrate to reflect EUV light and a patterned absorber film provided on the multilayer reflective film to absorb EUV light.

EUV light incident on the reflective mask from an illumination optical system of exposure equipment is reflected in areas (opening areas) where the absorber film is not present and is absorbed in areas (non-opening areas) where the absorber film is present. Consequently, the mask pattern is transferred as a resist pattern onto a wafer through a reductive projection optical system of exposure equipment, and then, the subsequent processing is carried out.

In a reflective mask blank, a hard mask film may be provided on a side of an absorber film opposite to a multilayer reflective film for the purpose of further line width reduction.

In general, dry etching is often used for etching of the absorber film. When the reflective mask blank is provided with the hard mask film, the hard mask film serves as a mask during dry etching of the absorber film. In such a case, there is no need for a photoresist to serve as a dry etching mask during production of the reflective mask so that the photoresist for forming a resist pattern corresponding to the pattern of the absorber film can be made small in thickness. This allows finer patterning of the absorber film, enabling the formation of a finer resist pattern on a wafer.

As an example of the reflective mask blank with such a hard mask film, Patent Document 1 discloses a reflective mask blank having a hard mask film containing chromium, nitrogen and hydrogen.

### PRIOR ART DOCUMENTS

### Patent Documents

Patent Document 1: WO 2012/105508

### DISCLOSURE OF INVENTION

### Technical Problem

With the recent demand for finer patterns formed using reflective masks, there has been a demand for reflective mask blanks from which reflective masks with finer absorber film patterns can be obtained. Hereinafter, an absorber film pattern of a reflective mask is also simply referred to as a “mask pattern”.

When the present inventors have studied the technique disclosed in Patent Document 1 and found that it is difficult by the disclosed technique to form fine mask patterns as recently demanded. Further, during the production of reflective masks, the reflective properties of the reflective masks often deteriorate.

The present invention has been made in view of the above-mentioned problems. It is an object of the present invention to provide a reflective mask blank capable of easily forming a fine mask pattern and less likely to cause reflective property deterioration of a multilayer reflective film during the production of a reflective mask. It is also an object of the present invention to provide a method for producing a reflective mask blank, a reflective mask and a method for producing a reflective mask.

### Solution to Problem

As a result of intensive studies made on the above-mentioned problems, the present inventors have found that it is important to adjust the chemical resistance of a hard mask film and the dry etching ratio between a protective film and the hard mask film, and then, have accomplished the present invention.

In other words, the present inventors have found the following solutions to the above-mentioned problems.
[1] A reflective mask blank comprising, in order:
   a substrate;
   a multilayer reflective film to reflect EUV light;
   a protective film;
   an absorber film; and
   a hard mask film,
   wherein the protective film comprises more than 50 at % of at least one element selected from the group consisting of rhodium, palladium, iridium and platinum, and
   wherein the hard mask film comprises ruthenium.
[2] The reflective mask blank according to [1], wherein:
   the hard mask film consists only of ruthenium, or
   the hard mask film comprises ruthenium and at least one element selected from the group consisting of boron, carbon, nitrogen, oxygen, titanium, chromium, zirconium, niobium, molybdenum, palladium, tantalum and iridium.
[3] The reflective mask blank according to [1] or [2], wherein the hard mask film comprises 50 to 100 at % of ruthenium.
[4] The reflective mask blank according to any one of [1] to [3], wherein a film thickness of the hard mask film is 0.3 to 30 nm.
[5] The reflective mask blank according to any one of [1] to [4], wherein the protective film further comprises at least one element selected from the group consisting of boron, carbon, nitrogen, oxygen, titanium, zirconium, niobium, molybdenum and tantalum.
[6] The reflective mask blank according to any one of [1] to [5], further comprising an interlayer film between the protective film and the multilayer reflective film, wherein the interlayer film consists only of ruthenium, or comprises ruthenium and at least one element selected from the group consisting of boron, carbon, nitrogen, oxygen, silicon, titanium, chromium, zirconium, niobium, molybdenum, palladium and tantalum.
[7] The reflective mask blank according to any one of [1] to [6], wherein the absorber film comprises at least one metal selected from the group consisting of Ta, Ti, Sn, Ir, Re, Nb, Mo and Cr.
[8] The reflective mask blank according to any one of [1] to [7], wherein the ratio (ER_{ABS}/ER_{HM}) of a dry etching rate (ER_{ABS}) of the absorber film to a dry etching rate (ER_{HM}) of the hard mask film is higher than or equal to 50 and lower than or equal to 1000.
[9] The reflective mask blank according to any one of [1] to [8], wherein the ratio (ER_{HM}/ER_{CAP}) of a dry etching rate (ER_{HM}) of the hard mask film to a dry etching rate (ER_{CAP}) of the protective film is higher than or equal to 30 and lower than or equal to 500.
[10] A reflective mask comprising an absorber film pattern formed by patterning the absorber film of the reflective mask blank as defined in any one of [1] to [9].
[11] A method for producing a reflective mask, comprising patterning the absorber film of the reflective mask blank as defined in any one of [1] to [9].
[12] A method for producing a reflective mask blank, comprising forming a multilayer reflective film to reflect EUV light, an interlayer film, a protective film, an absorber film and a hard mask film in order on a substrate,
   wherein the protective film comprises more than 50 at % of at least one element selected from the group consisting of rhodium, palladium, platinum and iridium,
   wherein the hard mask film comprises ruthenium, and
   wherein the forming is carried out continuously, without exposure to air, from start of the forming of the multilayer reflective film to completion of the forming of the protective film.

### Advantageous Effects of Invention

The present invention provides a reflective mask blank capable of easily forming a fine mask pattern and less likely to cause reflective property deterioration of a multilayer reflective film during the production of a reflective mask.

The present invention also provides a method for producing a reflective mask blank, a reflective mask, and a method for producing a reflective mask.

### BRIEF DESCRIPTION OF DRAWINGS

FIG. 1 is a schematic view illustrating an example of an embodiment of the reflective mask blank of the present invention.

FIGS. 2(a) to 2(f) are schematic views illustrating an example of a process for producing a reflective mask using the reflective mask blank of the present invention.

### DESCRIPTION OF EMBODIMENTS

Hereinafter, the present invention will be described in detail below.

It should be understood that, although the following description of the features of the present invention will be made based on typical embodiments of the present invention, these typical embodiments are not intended to limit the present invention thereto.

The following expressions used in the present specification have the following meanings.

In the present specification, a numerical range expressed using “to” means a range including numerical values described before and after “to” as lower and upper limits.

In the present specification, elements such as boron, carbon, nitrogen, oxygen, silicon, titanium, chromium, zirconium, niobium, molybdenum, ruthenium, rhodium, palladium, tantalum, rhenium, iridium and platinum etc. may be respectively expressed by their corresponding chemical symbols (B, C, N, O, Si, Ti, Cr, Zr, Nb, Mo, Ru, Rh, Pd, Ta, Re, Ir and Pt etc.).

### Reflective Mask Blank

The reflective mask blank of the present invention has a substrate, a multilayer reflective film to reflect EUV light, a protective film, an absorber film and a hard mask film stacked in this order, wherein the protective film contains more than 50 at % of at least one element selected from the group consisting of Rh, Pd, Ir and Pt, and wherein the hard mask film contains Ru.

The reflective mask blank of the present invention will be described below with reference to the drawings.

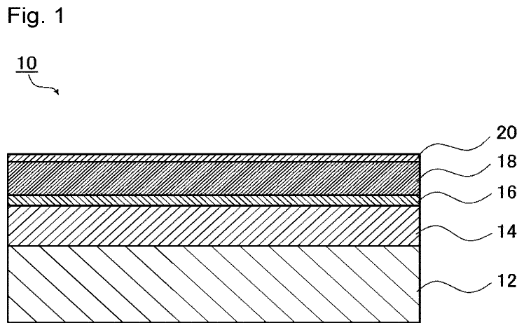

FIG. 1 is a cross-sectional view illustrating an example of an embodiment of the reflective mask blank of the present invention. A reflective mask blank 10 shown in FIG. 1 has a substrate 12, a multilayer reflective film 14, a protective film 16, an absorber film 18 and a hard mask film 20 stacked in this order.

The protective film 16 contains more than 50 at % of at least one element selected from the group consisting of Rh, Pd, Ir and Pt. The hard mask film 20 contains Ru.

Although not shown in FIG. 1, the reflective mask blank 10 may have a back-side conductive film on a side of the substrate 12 opposite to the hard mask film as will be described later. Further, the reflective mask blank 10 may have an interlayer film between the protective film 16 and the multilayer reflective film 14 as will be described later.

The mechanism by which the reflective mask blank of the present invention is capable of easily forming a fine mask pattern and less likely to cause reflective property deterioration of the multilayer reflective film during the production of a reflective mask is not entirely clear, but is assumed to be as follows by the present inventors.

In the reflective mask blank of the present invention, the hard mask film has excellent chemical resistance because of containing Ru. When the chemical resistance of the hard mask film is excellent, the hard mask film is less likely to be reduced in thickness by contact with a chemical liquid for peeling of a resist pattern formed on the hard mask film. The hard mask film can be thus formed with a small thickness. As a consequence, a resist pattern, which serves as a mask during patterning of the hard mask film, can also be formed with a small thickness. When the thickness of the resist pattern is small, the resist pattern is easy to form in a highly fine pattern shape. It is therefore considered that it is possible to easily form a fine mask pattern.

Further, in the production of a reflective mask, the absorber film is often dry-etched into a pattern with the use of the patterned hard mask film as a mask until the protective film is exposed. The hard mask film is removed after patterning of the absorber film by dry etching; and dry etching treatment is often used for the removal of the hard mask film. In this step, the hard mask film and the absorber film are subjected to dry etching treatment. Here, the protective film containing more than 50 at % of at least one element selected from the group consisting of Rh, Pd, Ir and Pt is more resistant to dry etching than the hard mask film containing Ru so that the hard mask film containing Ru is easily selectively removed. The protective film remains with a predetermined thickness and functions to protect the multilayer reflective film. It is therefore considered that the reflective properties of the multilayer reflective film are less likely to deteriorate.

In the following, the configuration of the reflective mask blank of the present invention will be described.

### Substrate

It is preferable that the substrate in the reflective mask blank of the present invention has a low thermal expansion coefficient. When the thermal expansion coefficient of the substrate is low, it is possible to suppress a distortion in the absorber film pattern due to heat generated during EUV exposure.

The thermal expansion coefficient of the substrate at 20° C. is preferably 0±1.0×10⁻⁷/° C., more preferably 0±0.3×10⁻⁷/° C.

As a material having a low thermal expansion coefficient, SiO₂—TiO₂ glass may be mentioned. The material of the substrate is however not limited to this glass. Substrates of crystallized glass with a β-quartz solid solution precipitated therein, quartz glass, metallurgical grade silicon, metal, and the like are also usable.

The SiO₂—TiO₂ glass is preferably quartz glass having a SiO₂ content of 90 to 95 mass % and a TiO₂ content of 5 to 10 mass %. When the TiO₂ content is 5 to 10 mass %, the linear expansion coefficient of the glass at around room temperature is substantially zero so that almost no dimensional change occurs at around room temperature. The SiO₂—TiO₂ glass may contain any trace component other than SiO₂ and TiO₂.

It is preferable that a surface (hereinafter also referred to as a “first main surface”) of the substrate on which the multilayer reflective film is stacked is high in surface smoothness. The surface smoothness of the first main surface can be evaluated on the basis of surface roughness. The surface roughness of the first main surface is preferably 0.15 nm or less in terms of the root mean square roughness Rq. Here, the surface roughness can be measured with an atomic force microscope, and will be described as the root mean square roughness Rq according to JIS B0601.

From the viewpoint of improving the pattern transfer accuracy and positional accuracy of a reflective mask obtained from the reflective mask blank, the first main surface is preferably surface-processed to a predetermined level of flatness. The flatness of the substrate at a predetermined area (for example, an area of 132 mm×132 mm) of the first main surface is preferably 100 nm or less, more preferably 50 nm or less, still more preferably 30 nm or less. The flatness can be measured with a flatness measurement system manufactured by FUJINON Corporation.

The size and thickness etc. of the substrate are determined as appropriate depending on the design value of the mask and the like. For example, the substrate may be formed with an outer size of 6 inches (152 mm) square and a thickness of 0.25 inches (6.3 mm).

Further, the substrate is preferably high in rigidity in order to prevent deformation due to stress of the film (multilayer reflective film, absorber film or the like) formed on the substrate. For example, the Young's modulus of the substrate is preferably 65 GPa or higher.

### Multilayer Reflective Film

The multilayer reflective film in the reflective mask blank of the present invention is not particularly limited as long as it has properties required for reflective films of EUV mask blanks. It is preferable that the multilayer reflective film has a high EUV light reflectance. More specifically, when a surface of the multilayer reflective film is irradiated with EUV light at an incident angle of 6°, the maximum reflectance of EUV light with a wavelength near 13.5 nm from the multilayer reflective film is preferably 60% or higher, more preferably 65% or higher. Even when the protective film is stacked on the multilayer reflective film, the maximum reflectance of EUV light with a wavelength near 13.5 nm from the multilayer reflective film is also preferably 60% or higher, more preferably 65% or higher.

As the multilayer reflective film, generally used is a multilayer reflective film having a plurality of high refractive index layers of high EUV refractive index and low refractive index layers of low EUV refractive index alternately stacked together to achieve a high EUV light reflectance.

Assuming a stacked unit in which a high refractive index layer and a low refractive index layer are stacked in this order from the substrate side as one cycle, the multilayer reflective film may have a laminated structure formed by a plurality of cycles. Assuming a stacked unit in which a low refractive index layer and a high refractive index layer are stacked in this order from the substrate side as one cycle, the multilayer reflective film may have a laminated structure formed by a plurality of cycles.

The high refractive index layer can be a layer containing Si. Examples of the Si-containing material include elemental Si and a Si compound containing Si and at least one selected from the group consisting of B, C, N and O. With the use of such Si-containing high refractive index layers, a reflective mask with a high EUV light reflectance can be obtained.

The low refractive index layer can be a layer containing a metal selected from the group consisting of Mo, Ru, Rh and Pt or an alloy thereof.

In the high refractive index layer, Si is widely used. In the low refractive index layer, Mo is widely used. In other words, the most commonly used is a Mo/Si multilayer reflective film. The multilayer reflective film is however not limited to this type. Other examples of the multilayer reflective film usable include a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film and a Si/Ru/Mo/Ru multilayer reflective film.

The thickness of each of the layers and the number of repeating units of the layers in the multilayer reflective film are selected as appropriate depending on the types of the film materials used and the EUV light reflectance required of the reflective film. Taking a Mo/Si multilayer reflective film as an example, the multilayer reflective film with a maximum EUV light reflectance of 60% or higher can be obtained by alternately stacking Mo layers of 2.3±0.1 nm thickness and Si layers of 4.5±0.1 nm thickness such that the number of repeating units of these layers ranges from 30 to 60.

Each of the layers of the multilayer reflective film can be formed with a desired thickness by a known film formation method such as a magnetron sputtering method, an ion beam sputtering method or the like. For example, when the multilayer reflective film is formed by ion beam sputtering, the sputtering is performed with the supply of ion particles from an ion source to a target of the high refractive index material and to a target of the low refractive index material. In the case where the multilayer reflective film is a Mo/Si multilayer reflective film, for example, a Si layer of predetermined thickness is first formed on the substrate by ion beam sputtering using a Si target. Then, a Mo layer of predetermined thickness is formed by ion beam sputtering using a Mo target. Assuming such stacking of Si and Mo layers as one cycle, the Mo/Si multilayer reflective film is formed by 30 to 60 cycles of stacking.

### Protective Film

The protective film in the reflective mask blank of the present invention contains more than 50 at % of at least one element (hereinafter also referred to as a “first specific element”) selected from the group consisting of Rh, Pd, Ir and Pt.

The protective film performs the function of, during patterning of the absorber film by an etching process (in general, a dry etching process), protecting the multilayer reflective film from damage by the etching process. The protective film also performs the function of protecting the multilayer reflective film during removal of the hard mask film.

Here, the expression “containing more than 50 at % of the first specific element” means that: when one type of element is contained as the first specific element, the content of such one type of element to all the atoms in the protective film is more than 50 at %; and, when two or more types of elements are contained as the first specific element, the total content of such two or more types of elements to all the atoms in the protective film is more than 50 at %.

The protective film is not particularly limited as long as it contains more than 50 at % of the first specific element. From the viewpoint of making reflective property deterioration of the multilayer reflective film further less likely to occur, the protective film preferably contains at least Rh, more preferably more than 50 at % of Rh.

The protective film may consist only of the first specific element, or may contain an additional element. The additional element can be at least one element selected from the group consisting of Si, Ti, Nb, Mo, Ru, Ta and Zr. At least one element selected from the group consisting of B, C, N and O may be contained as the additional element.

The content of the first specific element is more than 50 at %. From the viewpoint of making reflective property deterioration of the multilayer reflective film further less likely to occur, the content of the first specific element is preferably 60 at % or more, more preferably 80 at % or more, still more preferably 90 at % or more. The protective film may consist only of the first specific element.

The type and content of the element in the protective film can be measured by X-ray photoelectron spectroscopy (XPS). In the case where the type and content of the element in the protective film is measured by XPS, the measurement is conducted after the layer present on the side of the protective film opposite to the substrate is removed by sputtering etc.

The film thickness of the protective film is not particularly limited as long as the protective film performs its function. From the viewpoint of maintaining the reflectance of EUV light from the multilayer reflective film, the film thickness of the protective film is preferably 1 to 10 nm, more preferably 1.5 to 6 nm, still more preferably 2 to 5 nm.

The film thickness of the protective film can be measured by X-ray reflectometry (XRR).

The protective film can be formed by a known film formation method such as a magnetron sputtering method, an ion beam sputtering method or the like. In the case where a Rh film is formed by magnetron sputtering, the sputtering is preferably performed using a Rh target as the target and Ar gas as the sputtering gas.

### Interlayer Film

The reflective mask blank of the present invention may have an interlayer film between the protective film and the multilayer reflective film.

The interlayer film is a layer different from the protective film and is made of a material having a different composition from that of the protective film.

The material of the interlayer film is preferably a material containing at least one element (hereinafter also referred to as a “second specific element”) selected from the group consisting of Ru, Rh, Pd, Ir and Pt. Among others, a material containing at least one element selected from the group consisting of Ru and Rh is preferred. More preferred is a material containing Ru.

The interlayer film may consist only of the second specific element, or may contain an additional element. The additional element can be at least one element selected from the group consisting of Si, Ti, Cr, Zr, Nb, Mo, Pd and Ta. At least one element selected form the group consisting of B, C, N and O may be contained as the additional element.

In the case where the second specific element is contained in the interlayer film, the content of the second specific element is preferably more than 50 at %, more preferably 60 at % or more, still more preferably 80 at % or more, particularly preferably 90 at % or more. The interlayer film may consist only of the second specific element.

The film thickness of the interlayer film is preferably 0.3 to 10 nm, more preferably 0.5 to 6 nm, still more preferably 1 to 5 nm.

It is also preferable that the sum of the film thickness of the interlayer film and the film thickness of the protective film is controlled to within the above preferable protective film thickness range.

Here, the type and content of the element in the interlayer film can be measured by the same method as for the protective film.

Further, the film thickness of the interlayer film can be measured by the same method as for the protective film.

### Absorber Film

The absorber film in the reflective mask blank of the present invention is required to, during patterning of the absorber film, generate a high contrast between EUV light reflected by the multilayer reflective film and EUV light reflected by the absorber film.

The patterned absorber film (absorber film pattern) may serve as a binary mask to absorb EUV light, or may serve as a phase shift mask to reflect EUV light and generate a contrast by interference of the reflected light with EUV light from the multilayer reflective film.

In the case where the absorber film pattern is used as a binary mask, the absorber film needs to absorb EUV light and show a low EUV light reflectance. More specifically, when a surface of the absorber film is irradiated with EUV light, the maximum reflectance of EUV light with a wavelength near 13.5 nm from the absorber film is preferably 2% or lower.

The absorber film may contain, in addition to at least one metal selected from the group consisting of Ta, Ti, Sn, Ir, Re, Nb, Mo and Cr, at least one element selected form the group consisting of O, N, B, Hf and H. Among others, the absorber film preferably contains Ta together with N or B. By containing N or B, the crystalline state of the absorber film can be made amorphous or microcrystalline.

The crystalline state of the absorber film is preferably amorphous. This leads to improved smoothness and flatness of the absorber film. When the smoothness and flatness of the absorber film is improved, the absorber film pattern can be reduced in edge roughness and improved in dimensional accuracy.

In the case where the absorber film pattern is used as a binary mask, the film thickness of the absorber film is preferably 40 to 70 nm, more preferably 50 to 65 nm.

In the case where the absorber film pattern is used as a phase shift mask, the reflectance of EUV light from the absorber film is preferably 2% or higher. In order to obtain a sufficient phase shift effect, the reflectance of EUV light from the absorber film is more preferably 9 to 15%. The use of the absorber film as a phase shift mask leads to an improved optical image contrast on a wafer and an increase of exposure margin.

Examples of the material for forming the phase shift mask include an alloy of Ta and Nb, an alloy of Ta and Re, an alloy of Ta and Mo, a TaRu alloy containing Ta and 0.1 to 10 at % of Ru to all the atoms, an oxide containing Ta or a TaNb alloy and oxygen, a nitride containing Ta or a Ta alloy and nitrogen, and an oxynitride containing Ta or a Ta alloy, oxygen and nitrogen. Among others, a Ta-containing material is preferred. A nitride of Ta or of a Ta alloy is more preferred.

In the case where the absorber film pattern is used as a phase shift mask, the film thickness of the absorber film is preferably 30 to 75 nm, more preferably 35 to 55 nm.

The absorber film may be a single-layer film or a multilayer film constituted by a plurality of film layers. In the case where the absorber film is a single-layer film, the number of process steps in the production of the mask blank can be reduced to obtain an improvement of production efficiency. In the case where the absorber film is a multilayer film, the layer of the absorber film opposite to the protective film may be an anti-reflective film for inspection of the absorber film pattern by irradiation with inspection light (e.g. light with a wavelength of 193 to 248 nm).

The material of the anti-reflective film may be, for example, a material containing Ta and O.

The absorber film can be formed by a known film formation method such as a magnetron sputtering method, an ion beam sputtering method or the like. For example, in the case where a Ta nitride film is formed as the absorber film by magnetron sputtering, the absorber film can be formed by performing the sputtering using a Ta target with the supply of a gas containing Ar gas and nitrogen gas.

### Hard Mask Film

The hard mask film in the reflective mask blank of the present invention contains Ru.

The hard mask film is not particularly limited as long as it contains Ru. From the viewpoint of easily forming a fine mask pattern and making reflective property deterioration of the multilayer reflective film further less likely to occur, the content of Ru is preferably 30 at % or more, more preferably 50 at % or more, sill more preferably 70 at % or more. The hard mask film may consist only of Ru, and the upper limit of the content of Ru is 100 at % or less.

Here, the expression “consist only of Ru” means that the content of Ru is 99 to 100 at %.

The hard mask film may contain an element other than Ru. The element other than Ru in the hard mask film can be at least one element selected from the group consisting of B, C, N, O, Ti, Cr, Zr, Nb, Mo, Pd, Ta and Ir. The element other than Ru in the hard mask film is preferably at least one element selected from the group consisting of B, C, N and O, more preferably at least one element selected from the group consisting o N and O, in view of the tendency of the hard mask film to become low in crystallinity.

The type and content of the element in the hard mask film can be measured by the same method as for the protective film.

The material of the hard mask film is preferably selected to be more resistant to dry etching than the material of the absorber film. By such preferable material selection, the hard mask film is difficult to dry-etch relative to the material of the absorber film.

The dry etching rate of the hard mask film is set such that the ratio of the dry etching rate (ER_{ABS}) of the absorber film to the dry etching rate (ER_{HM}) of the hard film mask, referred to as ER_{ABS}/ER_{HM}, is preferably 50 or higher, more preferably 100 or higher, still more preferably 150 or higher. The upper limit of the ER_{ABS}/ER_{HM} is not particularly limited, and is preferably 1000 or lower, more preferably 800 or lower, still more preferably 500 or lower, particularly preferably 300 or lower.

Here, the dry etching rate of the hard mask film and the dry etching rate of the absorber film refer to etching rates as measured under a gas and conditions for dry etching of the absorber film. The detailed measurement conditions are as described later in Examples.

The material of the protective film is preferably selected to be more resistant to dry etching than the material of the hard mask film. By such preferable material selection, the protective film is difficult to dry-etch relative to the material of the hard mask film.

The ratio of the dry etching rate (ER_{HM}) of the hard mask film to the dry etching rate (ER_{CAP}) of the protective film, referred to as ER_{HM}/ER_{CAP} is preferably 30 or higher, more preferably 40 or higher, still more preferably 50 or higher, particularly preferably 60 or higher, most preferably 70 or higher. When the ER_{HM}/ER_{CAP} is 30 or higher, the protective film is more resistant to dry etching than the hard mask film containing Ru so that the hard mask film containing Ru can be easily selectively dry-etched. The upper limit of the ER_{HM}/ER_{CAP} is not particularly limited, and is preferably 500 or lower, more preferably 300 or lower, still more preferably 200 or lower, particularly preferably 150 or lower.

Here, the dry etching rate of the hard mask film and the dry etching rate of the absorber film refer to etching rates as measured under a gas and conditions for dry etching of the absorber film. The detailed measurement methods are as described later in Examples.

In the case where the absorber film is provided with an anti-reflective film, the material of the hard mask film is preferably selected to be more resistant to dry etching than the material of the anti-reflective film. By such preferable material selection, the hard mask film is difficult to dry-etch relative to the material of the anti-reflective film.

The dry etching rate of the hard mask film is set such that the ratio of the dry etching rate (ER_{ARC}) of the anti-reflective film to the dry etching rate (ER_{HM}) of the hard mask film, referred to as ER_{ARC}/ER_{HM}, is preferably 5 or higher, more preferably 7 or higher. The upper limit of the ER_{ARC}/ER_{HM} is not particularly limited, and is, for example, 500 or lower.

Here, the dry etching rate of the hard mask film and the dry etching rate of the anti-reflective film refer to etching rates as measured under a gas and conditions for dry etching of the anti-reflective film. The detailed measurements methods are as described later in Examples.

From the viewpoint of making reflective property deterioration of the multilayer reflective film further less likely to occur, the material of the hard mask film is preferably selected to be less resistant to dry etching than the material of the protective film. By such preferable material selection, the hard mask film is easy to dry-etch relative to the material of the protective film.

The dry etching rate of the hard mask film is set such that the ratio of the dry etching rate (ER_{HM}) of the hard mask film to the dry etching rate (ER_{CAP}) of the protective film, referred to as ER_{HM}/ER_{CAP}, is preferably 10 or higher, more preferably 30 or higher. The upper limit of the ER_{HM}/ER_{CAP} is not particularly limited, and is, for example, 1000.

Here, the dry etching rate of the hard mask film and the dry etching rate of the protective film refer to etching rates as measured under a gas and conditions for dry etching of the hard mask film. The detailed measurement methods are as described later in Examples.

It is further preferable that the hard mask film has high resistance to chemicals and, in particular, high resistance to sulfuric acid-hydrogen peroxide mixture (SPM). More specifically, the hard mask film preferably shows no decrease or less decrease in its film thickness even by contact with SPM.

The detailed measurement method is as described later in Examples.

The film thickness of the hard film mask is preferably 0.3 to 30 nm, more preferably 0.5 to 20 nm, still more preferably 1 to 10 nm, particularly preferably 1 to 5 nm, from the viewpoint of more easily forming a fine mask pattern.

The film thickness of the hard mask film can be measured by the same method as for the protective film.

The film thickness of the hard mask film can be set according to the above etching rate ratios.

The hard mask film is preferably low in crystallinity and is more preferably amorphous.

The crystallinity of the hard mask film means that the hard mask film has a small crystallite size as determined from a diffraction chart measured by the X-ray diffraction (XRD) method. It can be said that, when no apparent diffraction peak is observed in the diffraction chart, the hard mask film is amorphous.

The detailed method for evaluating the crystallinity of the hard mask film is as described later in Examples.

When the hard mask film is low in crystallinity, irregularities on the boundary between the etched region and the non-etched region are less likely to occur during etching of the hard film mask so that it is possible to form a finer mask pattern. The degree of irregularities on the boundary is also referred to as edge roughness.

The hard mask film can be formed by a known film formation method such as a magnetron sputtering method, an ion beam sputtering method or the like. For example, in the case where a Ru film is formed as the hard mask film by ion beam sputtering, the hard mask film can be formed by performing the sputtering using a Ru target and irradiating the Ru target with an Ar ion beam.

### Back-Side Conductive Film

The reflective mask blank of the present invention may have a back-side conductive film formed on a surface (second main surface) of the substrate opposite the first main surface. The formation of the back-side conductive film enables handling of the reflective mask blank by electrostatic chuck.

It is preferable that the back-side conductive film has a low sheet resistance. The sheet resistance of the back-side conductive film is, for example, preferably 200 Ω/sq. or lower, more preferably 100 Ω/sq. or lower.

The material of the back-side conductive film can be widely selected from those described in publicly known literature. For example, a high dielectric constant coating as disclosed in JP-A-2003-501823, such as a coating of Si, Mo, Cr, CrON or TaSi, is applicable. The material of the back-side conductive film may be a Cr compound containing Cr and at least one selected from the group consisting of B, N, O and C, or a Ta compound containing Ta and at least one selected from the group consisting of B, N, O and C.

The film thickness of the back-side conductive film is preferably 10 to 1000 nm, more preferably 10 to 400 nm.

Furthermore, the back-side conductive film may have the function of adjusting stress on the second main surface side of the reflective mask blank. In other words, the back-side conductive film may function to keep the reflective mask blank flat by balancing with stress from the respective films formed on the first main surface side.

The back-side conductive film can be formed by a known film formation method such as a sputtering method e.g. a magnetron sputtering method or an ion beam sputtering method, a CVD method, a vacuum deposition method or an electrolytic plating method.

### Method for Producing Reflective Mask Blank

The methods for forming the respective films of the reflective mask blank are as described above.

The reflective mask blank of the present invention can be produced by sequentially forming the respective films on the substrate.

More specifically, the method for producing the reflective mask blank of the present invention may include forming the multilayer reflective film on the substrate; forming the protective film on the multilayer reflective film; forming the absorber film on the protective film; and forming the hard mask film on the absorber film. The method for producing the reflective mask blank of the present invention may further include forming a film other than the above films. For example, after the formation of the multilayer reflective film, the interlayer film may be formed on the multilayer reflective film, followed by the formation of the protective film on the interlayer film.

As described above, the protective film contains more than 50 at % of at least one element selected from the group consisting of Rh, Pd, Ir and Pt; and the hard mask film contains Ru.

In the case where, after the formation of the multilayer reflective film, the interlayer film is formed on the multilayer film and the protective film is formed on the interlayer film, it is preferable that the formation of the films is carried out continuously without exposure to air from start of the formation of the interlayer film until completion of the formation of the protective film. By carrying out such continuous film formation without exposure to air, it is possible to suppress the generation of oxides that can become a cause of reflectance deterioration. It is also preferable that the film formation is carried out continuously without exposure to air from start of the formation of the multilayer reflective film until completion of the formation of the protective film.

### Method for Producing Reflective Mask and Reflective Mask

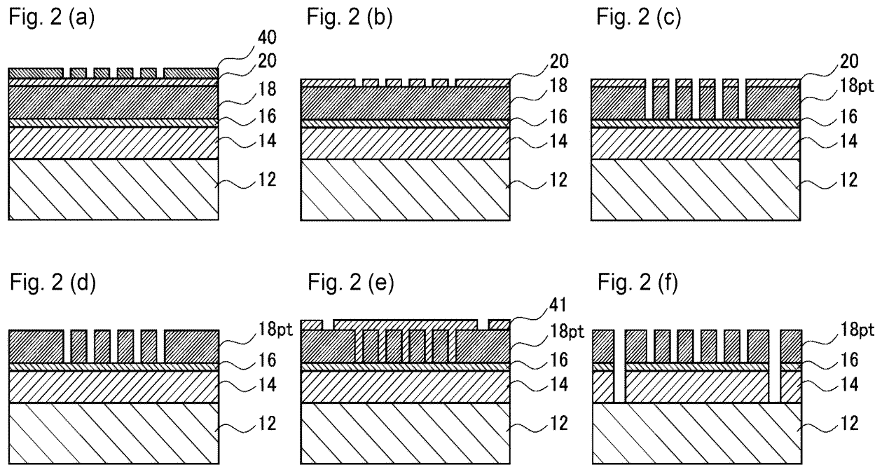

The reflective mask of the present invention can be produced by patterning the absorber film of the reflective mask blank of the present invention. An example of the method for producing the reflective mask will be described below with reference to FIGS. 2(a) to 2(f).

In FIG. 2(a), shown is a state that a resist pattern 40 is formed on the mask reflective mask blank 20 in which the substrate 12, the multilayer reflective film 14, the protective film 16, the absorber film 18 and the hard mask film 20 have been stacked in this order. The resist pattern 40 can be formed by a known method. For example, the resist pattern 40 is formed by applying a resist to the hard mask film 20 of the reflective mask blank and subjecting the applied resist to exposure and development. Here, the resist pattern 40 corresponds to a pattern to be formed on a wafer via the reflective mask.

Using the resist pattern 40 shown in FIG. 2(a) as a mask, the hard mask film 20 is etched and patterned into a shape corresponding to the resist pattern 40. Subsequently, the resist pattern 40 is removed to obtain the laminate as shown in FIG. 2(b).

The hard mask film 20 can be etched by a known method such as, for example, dry etching with a gas containing oxygen.

Further, the resist pattern 40 can be removed by a known method such as, for example, removal using a cleaning liquid. Examples of the cleaning liquid include sulfuric acid-hydrogen peroxide mixture (SPM), sulfuric acid, aqueous ammonia, ammonia-hydrogen peroxide mixture (APM), OH radical cleaning water and ozone water.

In the present invention, the hard mask film 20 is high in resistance to chemicals and thus is unlikely to be reduced in thickness by contact with the above cleaning liquid.

Next, using the patterned hard mask film 20 shown in FIG. 2(b) as a mask, the absorber film 18 is etched and patterned to obtain the laminate with an absorber film pattern 18pt as shown in FIG. 2(c). In the laminate shown in FIG. 2(c), the protective film 16 is being exposed.

The dry etching for formation of the absorber film pattern 18pt can be, for example, dry etching with a Cl-based gas or dry etching with a F-based gas.

The hard mask film 20 is then removed from the laminate shown in FIG. 2(c) to obtain the laminate as shown in FIG. 2(d). The removal of the hard mask film 20 can be conducted by the same method as that for etching the hard mask film 20.

During the removal of the hard mask film 20, not only the hard mask film 20 but also the protective film 16 are subjected to treatment for removal of the hard mask film 20. In the present invention, the protective film 16 is more resistant to etching than the hard mask film 20 so that the hard mask film 20 is removed selectively with less deterioration of the multilayer reflective film 14.

As shown in FIG. 2(e), a resist pattern 41 is then formed on the laminate shown in FIG. 2(d) in a shape corresponding to the frame of the exposure region. Dry etching is performed using the resist pattern 41 shown in FIG. 2(e) as a mask. This dry etching is performed until reaching the substrate 12. After the dry etching, the resist pattern 41 is removed to obtain the reflective mask as shown in FIG. 2(f).

The reflective mask obtained by patterning the absorber film of the reflective mask blank of the present invention is suitably usable as a reflective mask for EUV exposure.

### EXAMPLES

Now, the present invention will be described in further detail with reference to Examples.

The materials, amounts used, proportions, processing operations, processing procedures and the like shown in the following Examples can be changed as appropriate without departing from the spirit and scope of the present invention. The present invention is therefore by no means restricted to the following Examples.

Here, Ex. 1 to 6 correspond to Examples of the present invention; and Ex. 7 to 9 correspond to Comparative Examples.

### Ex. 1

First, a procedure for obtaining a reflective mask blank of Ex. 1 will be representatively described below.

### Substrate

As a substrate, a substrate of SiO₂—TiO₂ glass (outer size: 6 inches (152 mm) square, thickness: 6.3 mm) was provided. This glass substrate had a thermal expansion coefficient of 0.02×10⁻⁷/° C. at 20° C., a Young's modulus of 67 GPa, a Poisson's ratio of 0.17 and a specific stiffness of 3.07×107 m²/s². A quality assurance area on a first main surface of the substrate was formed with a root mean square roughness (RMS) of 0.15 nm or less and a flatness of 100 nm or less by polishing. On a second main surface of the substrate, a Cr film of 100 nm thickness was formed by magnetron sputtering. The sheet resistance of the Cr film was 100 Ω/sq.

### Multilayer Reflective Film

Next, a Mo/Si multilayer reflective film was formed as a multilayer reflective film on the first main surface of the substrate. The Mo/Si multilayer film was obtained by repeating the formation of a Si film (thickness: 4.5 nm) and a Mo film (thickness: 2.3 nm) by ion beam sputtering 40 times and, after the formation of the 40th Mo film, further forming a Si film (thickness: 4.5 nm). The total film thickness of the Mo/Si multilayer reflective film was 276.5 nm ((4.5 nm+2.3 nm)×40+4.5 nm).

### Protective Film

As a protective film, a Rh film (thickness: 2.5 nm) was formed by ion beam sputtering on the multilayer reflective film.

### Absorber Film and Anti-Reflective Film

An absorber film was formed by magnetron sputtering on the protective film.

The magnetron sputtering was performed using a Ta target in a mixed gas atmosphere of Ar, Kr and N₂ (Ar=67 vol %, Kr=17 vol %, N₂=16 vol %) to form a TaN film as the absorber film. The sputtering rate was 7.7 nm/min. The film thickness of the absorber film was 75 nm.

On the absorber film, an anti-reflective film was formed by magnetron sputtering. The magnetron sputtering was performed using a Ta target in a mixed gas atmosphere of Ar, O₂ and N₂ (Ar=60 vol %, O₂=30 vol %, N₂=10 vol %) to form a TaON film as the anti-reflective film. The sputtering rate was 1.32 nm/min. The film thickness of the anti-reflective film was 5 nm.

### Hard Mask Film

A hard mask film was formed by ion beam sputtering on the anti-reflective film. The hard mask film formed was a Ru film. The sputtering conditions for formation of the Ru film were as follows.
Target: Ru target
Sputtering gas: Ar gas (Ar: 100 vol %)
Voltage: 500 V
Sputtering rate: 0.023 nm/sec
Film thickness: 2.5 nm

The reflective mask blank of Ex. 1 was obtained by the procedure described above.

In the following, Ex. 2 to 8 will be described focusing only on the differences from the procedure for obtaining the reflective mask blank of Ex. 1.

### Ex. 2

A reflective mask blank of Ex. 2 was obtained by the same procedure as the reflective mask blank of Ex. 1, except that a RuN film was formed as the hard mask film by changing the sputtering conditions as shown below.
Target: Ru target
Sputtering gas: Mixed gas of Ar and N₂ (Ar: 75 vol %, N₂: 25 vol %)
Voltage: 500 V
Sputtering rate: 0.023 nm/sec
Film thickness: 2.5 nm

### Ex. 3

A reflective mask blank of Ex. 3 was obtained by the same procedure as the reflective mask blank of Ex. 1, except that a RuON film was formed as the hard mask film by changing the sputtering conditions as shown below.
Target: Ru target
Sputtering gas: Mixed gas of Ar, O₂ and N₂ (Ar: 60 vol %, O₂: 20 vol %, N₂: 20 vol %)
Voltage: 500 V
Sputtering rate: 0.023 nm/sec
Film thickness: 2.5 nm

### Ex. 4

A reflective mask blank of Ex. 4 was obtained by the same procedure as the reflective mask blank of Ex. 1, except that: an interlayer film was formed on the multilayer reflective film before the formation of the protective film; and the protective film was formed on the interlayer film.

As the interlayer film, a Ru film (thickness: 0.9 nm) was formed by ion beam sputtering. On the formed Ru film, a Rh film (thickness: 1.6 nm) was formed by ion beam sputtering. The film formation was carried out without exposure to air from start of the formation of the Ru film to completion of the formation of the Rh film.

### Ex. 5

A reflective mask blank of Ex. 5 was obtained by the same procedure as the reflective mask blank of Ex. 2, except that: before the formation of the protective film, an interlayer film was formed on the multilayer reflective film; and the protective film was formed on the interlayer film.

As the interlayer film, a Ru film (thickness: 0.9 nm) was formed by ion beam sputtering. On the formed Ru film, a Rh film (thickness: 1.6 nm) was formed on ion beam sputtering. The film formation was carried out without exposure to air from start of the formation of the Ru film to completion of the formation of the Rh film.

### Ex. 6

A reflective mask blank of Ex. 5 was obtained by the same procedure as the reflective mask blank of Ex. 3, except that: before the formation of the protective film, an interlayer film was formed on the multilayer reflective film; and the protective film was formed on the interlayer film.

As the interlayer film, a Ru film (thickness: 0.9 nm) was formed by ion beam sputtering. On the formed Ru film, a Rh film (thickness: 1.6 nm) was formed by ion beam sputtering. The film formation was carried out without exposure to air from start of the formation of the Ru film to completion of the formation of the Rh film.

### Ex. 7

A reflective mask blank of Ex. 7 was obtained by the same procedure as the reflective mask blank of Ex. 1, except that: a Ru film was formed as the protective film; and a CrO film was formed as the hard mask film.

More specifically, in the reflective mask blank of Ex. 7, a Ru film (thickness: 2.5 nm) was formed by ion beam sputtering as the protective film on the multilayer reflective film.

Further, the hard mask film was formed under the following conditions.
Target: Cr target
Sputtering gas: Mixed gas of Ar and O₂ (Ar: 35 vol %, O₂: 65 vol %, gas pressure: 1.5×10⁻¹ Pa)
Charged power density per target area: 4.1 W/cm²
Sputtering rate: 0.250 nm/sec
Distance between target and substrate: 300 mm
Film thickness: 10 nm

### Ex. 8

A reflective mask blank of Ex. 8 was obtained by the same procedure as the reflective mask blank of Ex. 7, except that a Ru film was formed as the hard mask film by changing the sputtering conditions as shown below.
Target: Ru target
Sputtering gas: Ar gas (gas pressure: 2.0×10⁻² Pa)
Voltage: 500 V
Sputtering rate: 0.023 nm/sec
Film thickness: 2.5 nm

### Ex. 9

A reflective mask blank of Ex. 9 was obtained by the same procedure as the reflective mask blank of Ex. 7, except that: before the formation of the protective film, an interlayer film was formed on the multilayer reflective film; and the protective film was formed on the interlayer film.

As the interlayer film, a Ru film (thickness: 0.9 nm) was formed by ion beam sputtering. On the formed Ru film, the Rh film (thickness: 1.6 nm) was formed by ion beam sputtering. The film formation was carried out without exposure to air from start of the formation of the Ru film and completion of the formation of the Rh film.

### Evaluation Methods and Criteria

### Chemical Resistance

The chemical resistance of the reflective mask blank was evaluated by the following procedure.

The reflective mask blank was first immersed in a chemical liquid under the conditions described below, after which the amount of change of the film thickness of the hard mask film was measured by XRR. The chemical liquid immersion conditions were as follows.
Chemical liquid: Sulfuric acid-aqueous hydrogen peroxide mixture (conc. sulfuric acid: 75 vol %, aqueous hydrogen peroxide: 25 vol %)
Conc. sulfuric acid: sulfuric acid 96 vol %, water 4 vol %
Aqueous hydrogen peroxide: hydrogen peroxide 30 to 35 vol %, water 65 to 70 vol %
Etching liquid temperature: 100° C.
Immersion time: 20 minutes

The evaluation was rated as: “A” when the amount of decrease of the film thickness of the hard mask film after the immersion in the chemical liquid relative to that before the immersion in the chemical liquid (film thickness before immersion-film thickness after immersion) was less than 0.1 nm; and “B” when the amount of decrease of the film thickness of the hard mask film was more than 0.1 nm.

The film thickness of the hard mask film was measured with SmartLab manufactured by Rigaku Corporation. In the following dry etching rate measurements, the film thicknesses of the hard mask film and the other films were measured by the same method.

### Dry Etching Rate Ratio (Absorber Film/Hard Mask Film)

A dry etching rate (ER_{HM1}) of the hard mask film and a dry etching rate (ER_{ABS}) of the absorber film were measured, and then, the ratio (ER_{ABS}/ER_{HM1}) of the dry etching rate of the absorber film to the dry etching rate of the hard mask film was calculated.

More specifically, dry etching was performed on a hard mask film and an absorber film, each of which had been formed as a model film on the same substrate as above, under the following conditions. From thickness changes of the hard mask film and the absorber film, the etching rates (dry etching rates) of the hard mask film and the absorber film were determined, respectively. The dry etching rate ratio (ER_{ABS}/ER_{HM1}) was calculated from the determined etching rates.

The dry etching was performed using an inductively coupled plasma (ICP) etching device under the following conditions.
ICP antenna bias output: 500 W
Substrate bias output: 15 W
Etching gas: Cl₂ gas
Cl₂ gas flow rate: 60 sccm
Etching pressure: 6.6×10⁻¹ Pa

Here, the unit “sccm” is an abbreviation for “standard cubic centimeter per minute” and refers to the flow rate (cm³/min) of a gas per minute, in terms of the volume value, at 1 atmosphere (1013.25 hPa) and 0° C.

The evaluation was rated as: “A” when the ER_{ABS}/ER_{HM1} was higher than or equal to 50; and “B” when the ER_{ABS}/ER_{HM1} was lower than 50.

### Dry Etching Rate Ratio (Anti-Reflective Film/Hard Mask Film)

A dry etching rate (ER_{HM2}) of the hard mask film and a dry etching rate (ER_{ARC}) of the anti-reflective film were measured, and then, the ratio (ER_{ARC}/ER_{HM2}) of the dry etching rate of the anti-reflective film to the dry etching rate of the hard mask film was calculated.

More specifically, dry etching was performed on a hard mask film and an anti-reflective film, each of which had been formed as a model film on the same substrate as above. From thickness changes of the hard mask film and the anti-reflective film, the etching rates (dry etching rates) of the hard mask film and the anti-reflective film were determined, respectively. The dry etching rate ratio (ER_{ARC}/ER_{HM2}) was calculated from the determined dry etching rates.

Here, the dry etching was performed using an ICP etching device under the following conditions.
ICP antenna bias output: 1200 W
Substrate bias output: 50 W
Etching gas: CF₄ gas
Flow rate of CF₄ gas: 60 sccm
Etching pressure: 4.0×10⁻¹ Pa

The evaluation was rated as: “A” when the ER_{ARC}/ER_{HM2} was higher than or equal to 5; and “B” when the ER_{ARC}/ER_{HM2} was lower than 5.

### Dry Etching Rate Ratio (Hard Mask Film/Protective Film)

A dry etching rate (ER_{CAP}) of the protective film and a dry etching rate (ER_{HM3}) of the hard mask film were measured, and then, the ratio (ER_{HM3}/ER_{CAP}) of the dry etching rate of the hard mask film to the dry etching rate of the protective film was calculated.

More specifically, dry etching was performed on a hard mask film and a protective film, each of which had been formed as a model film on the same substrate as above. From thickness changes of the hard mask film and the protective film, the etching rates (dry etching rates) of the hard mask film and the protective film were determined, respectively. The dry etching rate ratio (ER_{HM3}/ER_{CAP}) was calculated from the determined etching rates.

Here, the dry etching was performed using an ICP etching device under the following conditions.
ICP antenna bias output: 700 W
Substrate bias output: 10 W
Etching gas: Mixed gas of Cl₂ gas and O₂ gas
Flow rate of Cl₂ gas: 72 sccm
Flow rate of O₂ gas: 18 sccm
Etching pressure: 1.0×10⁰ Pa

The evaluation was rated as: “A” when the ER_{HM3}/ER_{CAP} was higher than or equal to 10; and “B” when the ER_{HM3}/ER_{CAP} was lower than 10.

### Crystallinity of Hard Mask Film

The crystallinity of the hard mask film was evaluated by measuring a diffraction chart of the hard mask film with an X-ray diffraction instrument (MiniFlexII) manufactured by Rigaku Corporation. In Table 1, FWHM refers to the full width at half maximum of the maximum intensity peak within the range of 20 from 35° to 60°. The crystallite size was calculated from the FWHM according to the Scherrer's equation.

In the table below, the evaluation was rated as “A” when the FWHM (half width) was greater than or equal to 3.0; “B” when the FWHM was greater than or equal to 0.5 and smaller than 3.0; and “C” when the FWHM was smaller than 0.5.

### Results

The configurations, measurement results and evaluation results of the respective reflective mask blanks are shown in the table below.

TABLE 1

Etching rate ratio

| | | | | | | Absorber | | | Anti-reflective |
|---|---|---|---|---|---|---|---|---|---|
| | Configuration | | | | | film/ | | | film/ |
| | | Anti- | | | Hard | Hard mask | Hard mask film/ | | Hard mask |
| | Absorber | reflective | Interlayer | Protective | mask | film | Protective film | | film |
| | film | film | film | film | film | Value | Value | Evaluation | Value |
| Ex. 1 | TaN | TaON | — | Rh | Ru | 205.3 | 79.0 | A | 22.3 |
| Ex. 2 | TaN | TaON | — | Rh | RuN | 205.3 | 79.0 | A | 22.3 |
| Ex. 3 | TaN | TaON | — | Rh | RuON | 86.8 | 132.3 | A | 7.7 |
| Ex. 4 | TaN | TaON | Ru | Rh | Ru | 205.3 | 79.0 | A | 22.3 |
| Ex. 5 | TaN | TaON | Ru | Rh | RuN | 205.3 | 79.0 | A | 22.3 |
| Ex. 6 | TaN | TaON | Ru | Rh | RuON | 86.8 | 132.3 | A | 7.7 |
| Ex. 7 | TaN | TaON | — | Ru | CrO | 20.5 | 1.4 | B | 53.0 |
| Ex. 8 | TaN | TaON | — | Ru | Ru | 205.0 | 1.0 | B | 22.3 |
| Ex. 9 | TaN | TaON | Ru | Rh | CrO | 20.5 | 111 | A | 53.0 |

| | |
|---|---|
| Chemical | Crystallinity |

| | resistance | FWHM | Crystallite | |
|---|---|---|---|---|
| | SPM | (deg.) | size (nm) | Evaluation |
| Ex. 1 | A | 0.4 | 224 | C |
| Ex. 2 | A | 1.0 | 94 | B |
| Ex. 3 | A | 5.7 | 16 | A |
| Ex. 4 | A | 0.4 | 224 | C |
| Ex. 5 | A | 1.0 | 94 | B |
| Ex. 6 | A | 5.7 | 16 | A |
| Ex. 7 | B | — | — | — |
| Ex. 8 | A | 0.4 | 224 | C |
| Ex. 9 | B | — | — | — |

It is apparent from the results shown in Table 1 that, in Ex. 7 and 8 in which the protective film did not contain more than 50 at % of at least one element selected from the group consisting of Rh, Pd, Ir and Pt, the hard mask film could not be removed selectively relative to the protective film; and, in a mask blank produced, reflective property deterioration of the multilayer reflective film would be likely to occur.

It is also apparent from the results shown in Table 1 that, in Ex. 7 and 9 in which the hard mask film did not contain Ru, the hard mask film was low in chemical resistance and thus could not be made small in thickness. Then, a resist would need to be formed with a large film thickness on the hard mask film for etching of the hard mask film. As the thickness of the resist increases, fine patterning of the resist becomes difficult. It is consequently difficult to form a fine mask pattern.

It is further apparent from comparison of Ex. 1 and 4 with Ex. 2, 3, 5 and 6 that the hard mask film becomes low in crystallinity when containing at least one element selected from the group consisting of B, C, N and O (preferably at least one element selected from the group consisting of N and O). When the crystallinity of the hard mask film becomes low, the above-described edge roughness tends to be small so that it is possible to easily form a finer mask pattern.

Furthermore, the minimum required film thickness of a resist to be formed on the hard mask film was calculated for each of the reflective mask blanks of Ex. 1 to 7.

More specifically, for each reflective mask blank, the film thickness of the hard mask film to be etched and removed away simultaneously with completion of the etching of the absorber film was calculated from the ratio between the etching rate of the absorber film and the etching rate of the hard mask film. In other words, the minimum film thickness required for the hard mask film to serve as an etching mask was calculated. This calculation result for each reflective mask blank is shown in the “Minimum required hard mask film thickness” column under the heading of “Consideration given only to absorber film” in Table 2.

As described above, the hard mask film is patterned into a mask by forming a resist pattern on the hard mask film and dry-etching the hard mask film with the use of the resist pattern as a mask. Therefore, the time required for removal of the hard mask film and the film thickness of the resist pattern required for patterning of the hard mask film are in a proportional relationship. Hence, the minimum required film thickness of the resist can be calculated for each of the reflective mask blanks of Ex. 1 to 7. The time required for removal of the hard mask film was calculated from the results shown in Table 1 and the above-calculated “minimum required hard mask film thickness”. This calculation result for each reflective mask blank is shown in the “Patterning time” column of the table below. The ratio of the resist film thickness calculated from the patterning time, to that calculated for Ex. 7, is also shown in the “Resist film thickness ratio” column of the table below.

Further, the “minimum required hard mask film thickness” with which the absorber film and the anti-reflective film could be patterned was calculated in the same manner as above, and the calculation result for each reflective mask film is shown in the “Minimum required hard mask film thickness” column under the heading of “Consideration given to absorber film and anti-reflective film” in Table 2. The “patterning time” and the “resist film thickness ratio” were also calculated in the same manner as above, and the calculation results are shown in the columns under the heading of “Consideration given to absorber film and anti-reflective film”.

The lower the resist film thickness ratio, the smaller the thickness of the resist required for each of the reflective mask blank of Ex. 1 to 7.

TABLE 2

| | Consideration given | | | Consideration given to absorber | | |
|---|---|---|---|---|---|---|
| | only to absorber film | | | film and anti-reflective film | | |
| | Minimum | | | Minimum | | |
| | required hard | | Resist film | required hard | | Resist film |
| | mask film | Patterning | thickness | mask film | Patterning | thickness |
| | thickness (nm) | time (min) | ratio (—) | thickness (nm) | time (min) | ratio (—) |
| Ex. 1 | 0.37 | 0.02 | 0.14 | 0.59 | 0.02 | 0.22 |
| Ex. 2 | 0.37 | 0.02 | 0.14 | 0.59 | 0.02 | 0.22 |
| Ex. 3 | 0.86 | 0.02 | 0.20 | 1.52 | 0.04 | 0.34 |
| Ex. 4 | 0.37 | 0.02 | 0.14 | 0.59 | 0.02 | 0.22 |
| Ex. 5 | 0.37 | 0.02 | 0.14 | 0.59 | 0.02 | 0.22 |
| Ex. 6 | 0.86 | 0.02 | 0.20 | 1.52 | 0.04 | 0.34 |
| Ex. 7 | 3.65 | 0.11 | 1.00 | 3.75 | 0.11 | 1.00 |

It is apparent from the results shown in Table 2 that the thickness of the resist to be formed on the hard mask film was smaller in the reflective mask blanks of Ex. 1 to 6 than in the reflective mask blank of Ex. 7, making it possible to easily form a highly fine resist pattern and thereby possible to easily form a finer mask pattern.

This application is a continuation of PCT Application No. PCT/JP2024/011707, filed on Mar. 25, 2025, which is based upon and claims the benefit of priority from Japanese Patent Application No. 2023-057859 filed on Mar. 31, 2023. The contents of those applications are incorporated herein by reference in their entireties.

### REFERENCE SYMBOLS

10: Reflective mask blank
12: Substrate
14: Multilayer reflective film
16: Protective film
18: Absorber film
18pt: Absorber film pattern
20: Hard mask film
40, 41: Resist pattern

What is claimed is:

1. A reflective mask blank comprising, in order:
a substrate;
a multilayer reflective film to reflect EUV light;
a protective film;
an absorber film; and
a hard mask film,
wherein the protective film comprises more than 50 at % of at least one element selected from the group consisting of rhodium, palladium, iridium and platinum, and
wherein the hard mask film comprises ruthenium.

2. The reflective mask blank according to claim 1, wherein:
the hard mask film consists only of ruthenium, or
the hard mask film comprises ruthenium and at least one element selected from the group consisting of boron, carbon, nitrogen, oxygen, titanium, chromium, zirconium, niobium, molybdenum, palladium, tantalum and iridium.

3. The reflective mask blank according to claim 1, wherein the hard mask film comprises 50 to 100 at % of ruthenium.

4. The reflective mask blank according to claim 1, wherein a film thickness of the hard mask film is 0.3 to 30 nm.

5. The reflective mask blank according to claim 1, wherein the protective film further comprises at least one element selected from the group consisting of boron, carbon, nitrogen, oxygen, titanium, zirconium, niobium, molybdenum and tantalum.

6. The reflective mask blank according to claim 1, further comprising an interlayer film between the protective film and the multilayer reflective film, wherein the interlayer film consists only of ruthenium or comprises ruthenium and at least one element selected from the group consisting of boron, carbon, nitrogen, oxygen, silicon, titanium, chromium, zirconium, niobium, molybdenum, palladium and tantalum.

7. The reflective mask blank according to claim 1, wherein the absorber film comprises at least one metal selected from the group consisting of Ta, Ti, Sn, Ir, Re, Nb, Mo and Cr.

8. The reflective mask blank according to claim 1, wherein the ratio (ER_{ABS}/ER_{HM}) of a dry etching rate (ER_{ABS}) of the absorber film to a dry etching rate (ER_{HM}) of the hard mask film is higher than or equal to 50 and lower than or equal to 1000.

9. The reflective mask blank according to claim 1, wherein the ratio (ER_{HM}/ER_{CAP}) of a dry etching rate (ER_{HM}) of the hard mask film to a dry etching rate (ER_{CAP}) of the protective film is higher than or equal to 30 and lower than or equal to 500.

10. A reflective mask comprising an absorber film pattern formed by patterning the absorber film of the reflective mask blank as defined in claim 1.

11. A method for producing a reflective mask, comprising patterning the absorber film of the reflective mask blank as defined in claim 1.

12. A method for producing a reflective mask blank, comprising forming a multilayer reflective film to reflect EUV light, an interlayer film, a protective film, an absorber film and a hard mask film in order on a substrate,
wherein the protective film comprises more than 50 at % of at least one element selected from the group consisting of rhodium, palladium, platinum and iridium,
wherein the hard mask film comprises ruthenium, and
wherein the forming is carried out continuously, without exposure to air, from start of the forming of the multilayer reflective film to completion of the forming of the protective film.
